(19) United States
(12) Patent Application Publication
(10) Pub. No.: US 2007/0178657 A1
(43) Pub. Date: Aug. 2, 2007

(54) Method of manufacturing a semiconductor device

(75) Inventors: Genichi Komuro, Kawasaki (JP); Kenji Kiuchi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/455,879

(22) Filed: Jun. 20, 2006

(30) Foreign Application Priority Data
Jan. 31, 2006 (JP) 2006-021628

(51) Int. Cl. H01L 21/20

(52) U.S. Cl. 438/396

(57) ABSTRACT

A semiconductor device manufacturing method whereby a capacitor protective layer for ferroelectric capacitors of FeRAM can be prevented from peeling off. A lower electrode layer, a ferroelectric layer and an upper electrode layer are successively formed one upon another. The upper electrode layer is etched to form an upper electrode pattern, then the ferroelectric layer is etched to form a ferroelectric pattern, and a chemical solution treatment is performed on the resulting structure by using a mixed liquid of ammonia, hydrogen peroxide and water. Subsequently, a capacitor protective layer is formed, and then the lower electrode layer is etched to form a lower electrode pattern. A volatile etching residue produced during the formation of the ferroelectric pattern and adhering to the wafer surface, including the exposed lower electrode layer, is removed by the chemical solution treatment, whereby the subsequently formed capacitor protective layer is prevented from peeling off.

### CROSS-REFERENCE TO RELATED APPLICATIONS

This application is based upon and claims the benefits of priority from the prior Japanese Patent Application No. 2006-021628, filed on Jan. 31, 2006, the entire contents of which are incorporated herein by reference.

### BACKGROUND OF THE INVENTION

1. Field of the Invention

The present invention relates to semiconductor device manufacturing methods, and more particularly, to a method of manufacturing a semiconductor device having a ferroelectric capacitor.

2. Description of the Related Art

Flash memory and ferroelectric memory are known as nonvolatile memory capable of retaining information even when the power is switched off.

Of these, flash memory has floating gates embedded in the gate insulating layers of IGFETs (Insulated Gate Field-Effect Transistors) and charges representing information are accumulated in the floating gates to retain the information. In the case of flash memory, however, a tunnel current needs to be passed through the gate insulating layers at the time of writing or erasing information, requiring relatively high voltage.

By contrast, ferroelectric memory, which is also referred to as FeRAM (Ferroelectric Random Access Memory), retains information by making use of the hysteresis of ferroelectric layers that ferroelectric capacitors have. The ferroelectric layer develops polarization dependent on the voltage applied between upper and lower electrodes of the capacitor, and spontaneous polarization remains even after the voltage is removed. As the polarity of the applied voltage is inverted, the spontaneous polarization is also inverted, and thus the directions of the spontaneous polarization are made to correspond to “1” and “0”, thereby allowing information to be written in the ferroelectric layers. FeRAM is advantageous over flash memory in that information can be written with lower voltage and also at higher speed.

It is known that the ferroelectric capacitors of FeRAM deteriorate in the electric characteristics on contact with moisture or hydrogen during the manufacturing process or in environments in which the FeRAM is used. To cope with this, after the ferroelectric capacitor is formed, a capacitor protective layer (e.g., alumina layer) for blocking moisture and hydrogen is formed on the surface of the ferroelectric capacitor to prevent the deterioration of the capacitor due to moisture or hydrogen (e.g., Unexamined Japanese Patent Publication No. 2004-63891).

FIGS. 5A through 5D are sectional views showing a principal part of a semiconductor device during the process of manufacturing a conventional FeRAM.

The memory cell structure of an FeRAM is constituted by a switching transistor and a ferroelectric capacitor. In the process of fabricating an FeRAM, a MOS (Metal Oxide Semiconductor) transistor as the switching transistor is formed first, and then a ferroelectric capacitor is formed on the transistor. In FIGS. 5A to 5D, only the part corresponding to the ferroelectric capacitor is shown.

To form the ferroelectric capacitor, first, a lower electrode layer 51, a ferroelectric layer 52 and an upper electrode layer 53 are successively formed on an insulating layer 50 (FIG. 5A). For the lower electrode layer 51, platinum (Pt) is used. For the ferroelectric layer 52, lead zirconate titanate (PZT) is used, and for the upper electrode layer 53, iridium oxide (IrOₓ) is used.

Subsequently, etching is performed with the use of resist masks with desired patterns, to form an upper electrode pattern 53a and a ferroelectric pattern 52a in this order (FIG. 5B).

Then, with the lower electrode layer 51 exposed on the surface of the wafer (semiconductor device), a first capacitor protective layer 54 is formed so as to cover the ferroelectric pattern 52a as well as the upper electrode pattern 53a (FIG. 5C).

Further, although not shown, the lower electrode layer 51 is machined to form a lower electrode pattern, and then a second capacitor protective layer (alumina layer) is formed, whereby the effect of blocking moisture and hydrogen can be enhanced.

When the etching is performed to form the ferroelectric pattern 52a, a volatile etching residue adheres to the wafer surface, including the exposed lower electrode layer 51. If the capacitor protective layer 54 is formed without removing the residue, a problem arises in that a part 54a of the capacitor protective layer peels off during the subsequent heat treatment, as shown in FIG. 5D.

If this occurs, it is highly possible that the capacitor characteristics deteriorate because of the peeling 54a of the capacitor protective layer, lowering reliability. Further, the peeling 54a of the capacitor protective layer possibly causes short circuit or the like, making the memory cell defective.

The problem may conceivably be solved by performing annealing before the formation of the capacitor protective layer 54 to volatilize the etching residue. If the annealing is conducted at high temperature, however, the electric characteristics of the ferroelectric capacitor deteriorate. Consequently, the annealing temperature cannot be set sufficiently high, and thus a satisfactory effect of removing the etching residue cannot be expected from the annealing.

### SUMMARY OF THE INVENTION

The present invention was created in view of the above circumstances, and an object thereof is to provide a method of manufacturing a semiconductor device whose capacitor protective layer can be prevented from peeling off.

To achieve the object, there is provided a method of manufacturing a semiconductor device having a ferroelectric capacitor. The manufacturing method comprises the step of successively forming a lower electrode layer, a ferroelectric layer and an upper electrode layer one upon another, the step of etching the upper electrode layer to form an upper electrode pattern, then etching the ferroelectric layer to form a ferroelectric pattern, and performing a chemical solution treatment on a resulting structure by using a mixed liquid of ammonia, hydrogen peroxide and water, the step of forming a capacitor protective layer subsequently to the chemical solution treatment, and the step of etching the lower electrode layer to form a lower electrode pattern after the capacitor protective layer is formed.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a flowchart outlining a semiconductor device manufacturing method according to an embodiment of the invention.

FIGS. 2A through 2D are sectional views showing a principal part of a semiconductor device during the process of forming a ferroelectric capacitor.

FIG. 3 is a sectional view showing a principal part of the ferroelectric capacitor.

FIGS. 4A and 4B illustrate wafer surface inspection results, wherein FIG. 4A shows the results of inspection of defects in the wafer surface of a semiconductor device obtained by a conventional manufacturing method, and FIG. 4B shows the results of inspection of defects in the wafer surface of a semiconductor device obtained by the manufacturing method according to the embodiment.

FIGS. 5A through 5D are sectional views showing a principal part of a semiconductor device during the process of fabricating a conventional FeRAM.

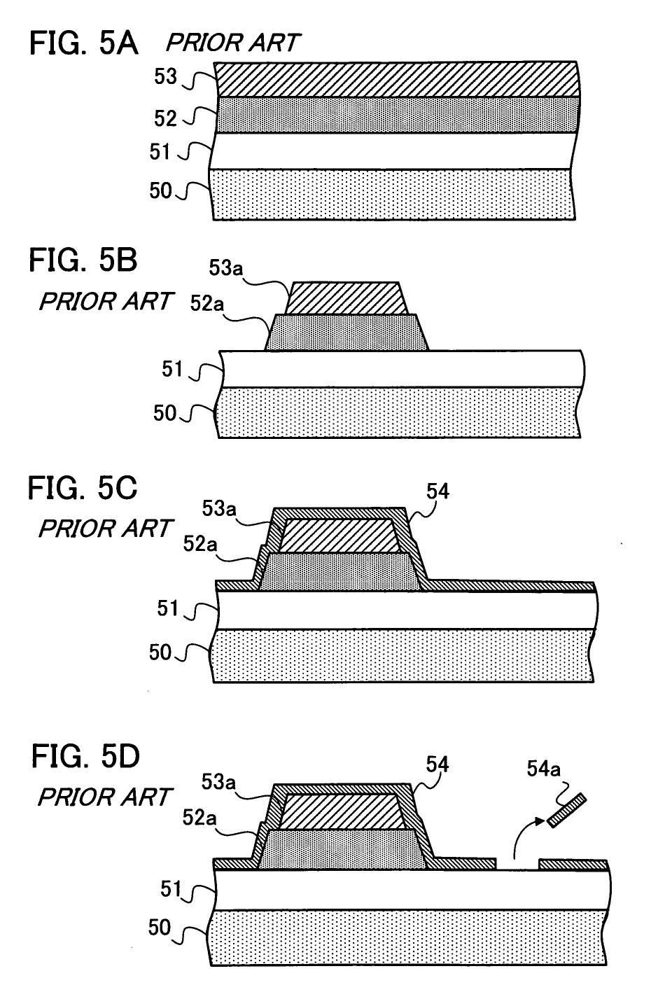

### DESCRIPTION OF THE PREFERRED EMBODIMENTS

Preferred embodiments of the present invention will be described in detail below with reference to the accompanying drawings.

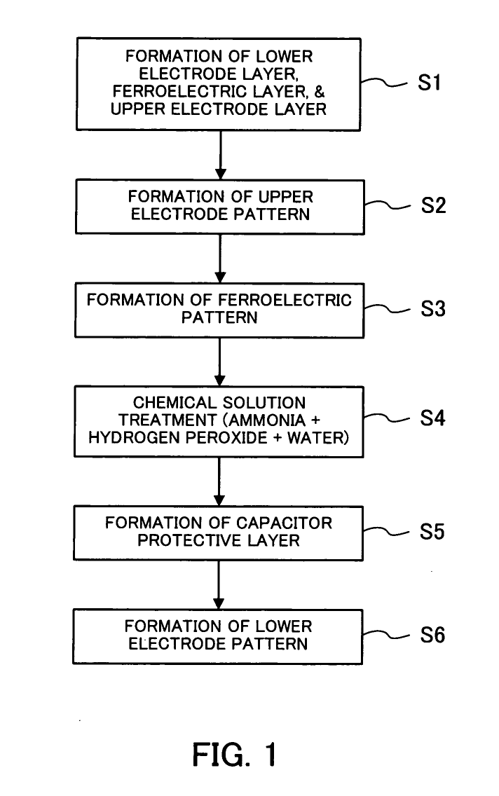

FIG. 1 is a flowchart outlining a semiconductor device manufacturing method according to an embodiment. More particularly, the figure illustrates the process of forming a ferroelectric capacitor constituting the memory cell structure of an FeRAM.

The memory cell structure of an FeRAM is composed of a switching transistor and a ferroelectric capacitor. In the process of fabricating an FeRAM, MOS transistors as the switching transistors are formed first, and then tungsten plugs for establishing electrical connection with upper layers are formed. Further, an SiON (silicon oxynitride) layer is formed so as to prevent oxidation of the tungsten plugs, and a silicon oxide layer is formed on the SiON layer. Subsequently, ferroelectric capacitors are formed on the silicon oxide layer.

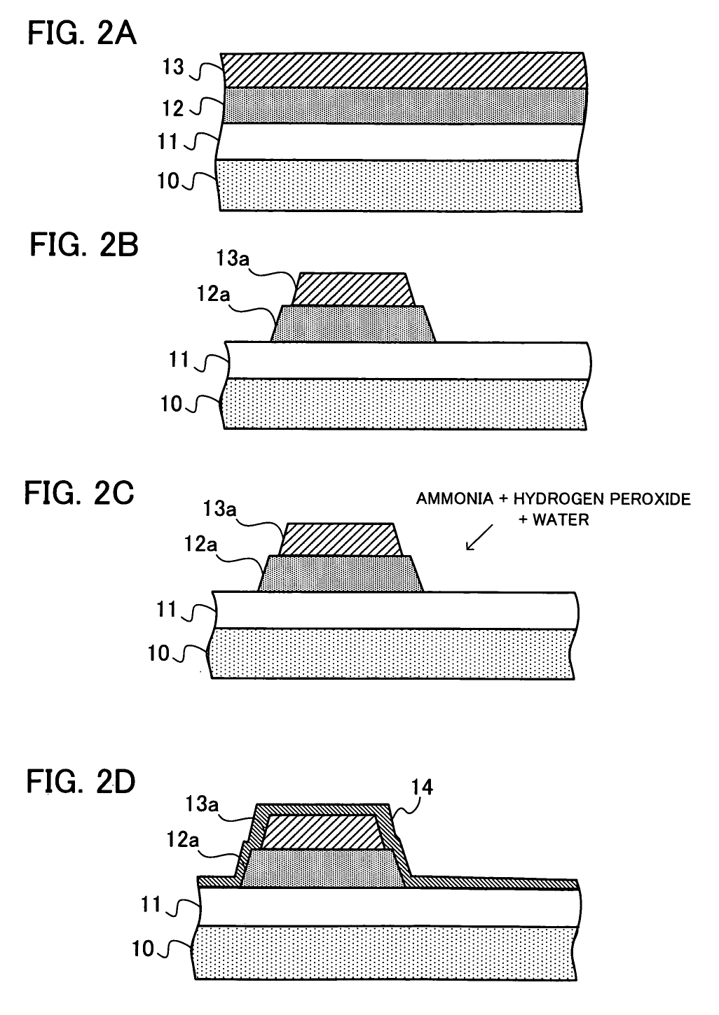

FIGS. 2A through 2D illustrate, in section, a principal part of a semiconductor device during the process of forming a ferroelectric capacitor.

FIG. 2A is a sectional view of the semiconductor device obtained by Step S1 in FIG. 1. In Step S1, a lower electrode layer 11, a ferroelectric layer 12 and an upper electrode layer 13, which are the materials of the ferroelectric capacitor, are successively formed on the silicon oxide layer 10.

For the lower electrode layer 11, Pt is used. For example, after an alumina layer (not shown) of 20 nm thick is formed on the silicon oxide layer 10, a Pt layer with a thickness of 150 nm is formed by sputtering. The alumina layer is formed so as to improve the orientation of a PZT layer used as the ferroelectric layer 12 as well as to enhance the adhesion of the lower electrode layer 11.

As the ferroelectric layer 12, a 150 nm-thick PZT layer, for example, is formed. After the ferroelectric layer 12 is formed, annealing is carried out for crystallization.

As the upper electrode layer 13, an IrOₓ layer with a thickness of, for example, 250 nm is formed by sputtering.

Subsequently, the step of patterning the ferroelectric capacitor is performed.

In Step S2, an upper electrode pattern is formed. Specifically, in this step, with a resist mask formed on the upper electrode layer 13, the upper electrode layer is etched to form an upper electrode pattern.

The etching is carried out by using, for example, an ICP (Inductively Coupled Plasma) etching system in which the chamber inner wall of an antenna section of the plasma source is made of quartz. The pressure in the chamber is set to 0.3 to 1.0 Pa, and a mixed gas of a halogen (in this instance, chlorine (Cl) is used) and argon (Ar) is introduced into the chamber at a total flow rate of 50 to 150 sccm with the gas flow ratio C1₂/Ar set to about 1/7 to 1/1. For the source power, power with a high frequency of 13.56 MHz and an output of 1000 to 2500 W is used. Also, the bias power is set so that the substrate bias voltage Vpp applied to the underside of the wafer when a high frequency of 200 to 800 kHz is used may fall within a range of 700 to 1500 V. For example, the bias power is set to about 600 to 1600 W.

After the upper electrode layer 13 is etched under the aforementioned conditions, the resist mask is ashed by means of an ashing system and the wafer surface is washed with water. Subsequently, in order to eliminate the damage caused by the layer formation and the etching, annealing is performed (at 650° C. in an oxygen atmosphere for one hour).

In Step S3, a ferroelectric pattern is formed.

After the annealing, a resist mask is formed on the exposed ferroelectric layer 12, which is then etched to form a ferroelectric pattern.

The etching is performed by using the ICP etching system. The etching conditions used in this case are as follows: The pressure in the chamber is set to 0.3 to 1.0 Pa, and a mixed gas of chlorine and argon is introduced into the chamber at a total flow rate of 50 to 150 sccm with the gas flow ratio C1₂/Ar set to about 1/7 to 5/1. Source power with a high frequency of 13.56 MHz is used and the output thereof is set to 1000 to 2500 W. Also, the bias power is set so that the substrate bias voltage Vpp applied to the underside of the wafer when a high frequency of 200 to 800 kHz is used may fall within a range of 500 to 1500 V. For example, the bias power is set to about 400 to 1600 W.

After the etching is performed, the resist mask is removed by ashing with the wafer kept inside the chamber (in a vacuum). The reason for removing the resist mask without taking the wafer out of the chamber is that if the wafer is exposed to the air without removing the resist mask, moisture in the air reacts with the residual gas, causing damage to the ferroelectric layer (PZT layer) 12. Also, the ashing needs to be performed, for example, in an oxygen atmosphere or a mixed gas atmosphere of oxygen and nitrogen, without using fluorine (F). If a gas containing fluorine is used, fluorine remains on the wafer and reacts with moisture in the air to form hydrogen fluoride (HF) when the wafer is exposed to the air, possibly causing damage to the PZT layer.

FIG. 2B is a sectional view of the semiconductor device obtained after Steps S2 and S3 in FIG. 1.

As a result of the removal of the resist mask in a vacuum, the structure as illustrated is obtained wherein the upper electrode pattern 13a is stacked on the ferroelectric pattern 12a.

FIG. 2C is a sectional view of the semiconductor device during Step S4 in FIG. 1.

Because of the preceding steps up to Step S3, an etching residue produced due to the formation of the upper electrode pattern 13a or due to the formation of the ferroelectric pattern 12a adheres to the wafer surface, including the exposed lower electrode layer 11. In Step S4, the etching residue is removed by a chemical solution treatment.

For the chemical solution treatment, a mixed liquid of ammonia (aqueous ammonia with an ammonia concentration of, e.g., 30%, is used), an aqueous solution of hydrogen peroxide (with a concentration of, e.g., 30%) and water is used. In the mixed liquid, the ratio of the concentration of ammonia to that of hydrogen peroxide is set to about 1/5 to 1/1, and the mixed liquid is used directly or after being diluted with pure water to a strength of 1/5 or above. Using the chemical solution prepared in this manner, the wafer is immersed in the solution at a temperature of 80° C. or below for five minutes or longer. At this time, the chemical solution may be stirred by using a pump or the like so that the solution can satisfactorily spread all over the wafer surface. Subsequently, the wafer is washed in water and then dried. Preferably, the wafer is dried by IPA (isopropyl alcohol) vapor drying.

The aforementioned chemical solution treatment makes it possible to remove the volatile etching residue adhering to the wafer surface.

Subsequently, the wafer is subjected to annealing (at 400° C. or lower in an oxygen atmosphere) and then a capacitor protective layer is formed. After the chemical solution treatment, the wafer is kept away from water until the capacitor protective layer is formed.

FIG. 2D is a sectional view of the semiconductor device obtained by Step S5 in FIG. 1. In Step S5, an alumina layer with a thickness of about 50 nm is formed as the capacitor protective layer 14. The wafer is then again subjected to annealing (at 550° C. in an oxygen atmosphere for about 60 minutes).

Subsequently, in Step S6, a resist mask is formed on the capacitor protective layer 14 and a lower electrode pattern is formed by etching.

The etching is carried out by using the ICP etching system. The etching conditions used in this case are as follows: The pressure in the chamber is set to 0.3 to 1.0 Pa, and a mixed gas of chlorine and argon is introduced into the chamber at a total flow rate of 50 to 150 sccm with the gas flow ratio C1₂/Ar set to about 1/7 to 1/1. Source power with a high frequency of 13.56 MHz is used and the output thereof is set to 1000 to 2500 W. Also, the bias power is set so that the substrate bias voltage Vpp applied to the underside of the wafer when a high frequency of 200 to 800 kHz is used may fall within a range of 700 to 1500 V. For example, the bias power is set to about 600 to 1600 W.

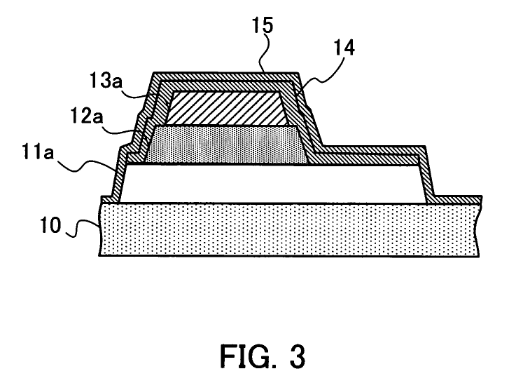

FIG. 3 is a sectional view showing a principal part of the ferroelectric capacitor.

Because of the above step, the lower electrode pattern 11a is formed, whereby the ferroelectric capacitor as illustrated is obtained in which the lower electrode pattern 11a, the ferroelectric pattern 12a and the upper electrode pattern 13a are stacked in tiers. Subsequently, an additional capacitor protective layer (alumina layer) 15 is formed and then wiring is formed to fabricate an FeRAM.

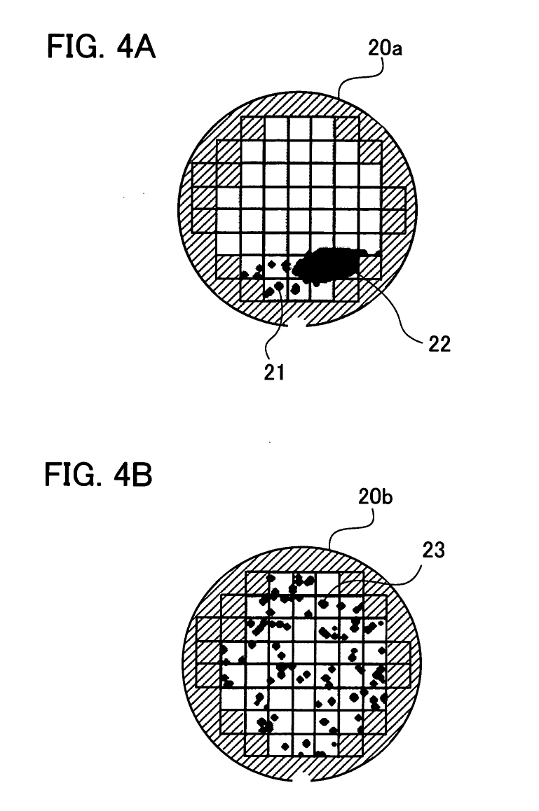

FIGS. 4A and 4B illustrate wafer surface inspection results, wherein FIG. 4A shows the results of inspection of defects in the wafer surface of a semiconductor device obtained by a conventional manufacturing method, and FIG. 4B shows the results of inspection of defects in the wafer surface of a semiconductor device obtained by the manufacturing method according to the embodiment.

In both cases, surface defects were inspected by using a wafer surface inspection system (from KLA-Tencor Corporation). The wafers were scanned for inspection from below as viewed in FIGS. 4A and 4B, wherein the hatching indicates non-inspection regions.

As shown in FIG. 4A, the wafer 20a obtained by the conventional manufacturing method had a part 22 where the alumina layer had peeled off, in addition to defects 21. When the wafer was inspected for defects, the inspection system terminated the inspection on detecting the peeled-off part 22, so that the cells located above the peeled-off part as viewed in the figure were left uninspected.

By contrast, the wafer 20b shown in FIG. 4B, which was obtained by the semiconductor device manufacturing method according to the embodiment, had no peeling of the alumina layer, and defects 23 could be fully inspected.

As described above, in the semiconductor device manufacturing method according to the embodiment, the chemical solution treatment using a mixed liquid of ammonia, hydrogen peroxide and water is carried out prior to the formation of the capacitor protective layer, in order to remove the volatile etching residue adhering to the wafer surface. Thus, since the capacitor protective layer is formed after the chemical solution treatment, it is possible to prevent the capacitor protective layer from peeling off during the subsequent steps such as high-temperature annealing. Accordingly, the ferroelectric capacitor can be prevented from being deteriorated in characteristics and the reliability thereof improves. Also, since short circuit or the like is not caused by peelings of the capacitor protective layer, defectives can be reduced in number and the yield improves.

According to the present invention, after the ferroelectric pattern is formed by etching, the chemical solution treatment is carried out by using a mixed liquid of ammonia, hydrogen peroxide and water, and therefore, the volatile etching residue adhering to the wafer surface, including the exposed lower electrode layer, is removed, thereby preventing the subsequently formed capacitor protective layer from peeling off. Consequently, deterioration in the characteristics of the ferroelectric capacitor can be prevented, thus improving its reliability, and also since short circuit or the like is not caused by peelings of the capacitor protective layer, defectives can be reduced in number, improving the yield.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method of manufacturing a semiconductor device having a ferroelectric capacitor, comprising the steps of:
successively forming a lower electrode layer, a ferroelectric layer and an upper electrode layer one upon another;
etching the upper electrode layer to form an upper electrode pattern, then etching the ferroelectric layer to form a ferroelectric pattern, and performing a chemical solution treatment on a resulting structure by using a mixed liquid of ammonia, hydrogen peroxide and water;
forming a capacitor protective layer subsequently to the chemical solution treatment; and
etching the lower electrode layer to form a lower electrode pattern after the capacitor protective layer is formed.

2. The method according to claim 1, wherein in the chemical solution treatment, the mixed liquid is stirred with a wafer immersed in the mixed liquid.

3. The method according to claim 1, wherein in the chemical solution treatment, temperature of the mixed liquid is set to 80° C. or below.

4. The method according to claim 1, wherein the mixed liquid has a ratio of concentration of ammonia to that of hydrogen peroxide ranging from 1/5 to 1/1.

5. The method according to claim 1, wherein the chemical solution treatment is continued for five minutes or longer.

6. The method according to claim 1, wherein water washing and isopropyl alcohol vapor drying are performed after the chemical solution treatment and before the formation of the capacitor protective layer.

7. The method according to claim 1, wherein annealing is performed at a temperature of 400° C. or below in an oxygen atmosphere before the capacitor protective layer is formed.

8. The method according to claim 1, wherein the capacitor protective layer is an alumina layer.

9. The method according to claim 1, wherein the ferroelectric pattern is formed from the ferroelectric layer by using an ICP etching system.

10. The method according to claim 9, wherein a mixed gas of argon and halogen gas is used as a gas atmosphere during the etching.

11. The method according to claim 1, wherein the chemical solution treatment removes an etching residue produced due to the formation of the upper electrode pattern or due to the formation of the ferroelectric pattern.

12. A semiconductor device with a ferroelectric capacitor, comprising:
a capacitor protective layer which is formed after a chemical solution treatment using a mixed liquid of ammonia, hydrogen peroxide and water is performed subsequently to successive formation of an upper electrode pattern and a ferroelectric pattern of the ferroelectric capacitor by etching.

13. The semiconductor device according to claim 12, wherein the capacitor protective layer is an alumina layer.

14. The semiconductor device according to claim 12, wherein the chemical solution treatment removes an etching residue produced due to the formation of the upper electrode pattern or due to the formation of the ferroelectric pattern.
